(19) United States
(12) Patent Application Publication
(10) Pub. No.: US 2026/0136453 A1
(43) Pub. Date: May 14, 2026

(54) COLD-BAR SOLDERING SYSTEMS AND METHODS

(71) Applicant: Lutron Technology Company LLC, Coopersburg, PA (US)

(72) Inventor: Lawrence Tyler Collins, Emmaus, PA (US)

(73) Assignee: Lutron Technology Company LLC, Coopersburg, PA (US)

(21) Appl. No.: 19/327,172

(22) Filed: Sep. 12, 2025

Related U.S. Application Data
(60) Provisional application No. 63/694,363, filed on Sep. 13, 2024.

(51) Int. Cl. H05K 1/02; H05K 3/341; H05K 3/3494

(52) U.S. Cl. CPC H05K 1/0212; H05K 1/0277; H05K 3/341; H05K 3/3494

(57) ABSTRACT

A flexible circuit board (FCB) can include one or more pads disposed on a first side of the FCB and a heating element having connections for coupling to an external power supply disposed on a second side of the FCB. A printed circuit board (PCB) can include one or more lands disposed on a surface of the PCB. Solder is disposed on each of the one or more lands. The one or more FCB pads are placed into contact with respective ones of the one or more PCB lands. A pressure application subsystem maintains even pressure on the portion of the FCB occupied by the one or more pads while the external power supply supplies power to the heating element. The thermal energy produced by the heating element causes the solder between the FCB pads and the PCB lands to reflow, physically and conductively coupling the FCB to the PCB.

### CROSS-REFERENCE TO RELATED APPLICATIONS

This application claims benefit of Provisional U.S. Patent Application No. 63/694,363, filed Sep. 13, 2024, the entire disclosures of which are hereby incorporated by reference herein their entirety.

### BACKGROUND

Hot bar soldering is a technique used to join two circuit boards. Solder is trapped between lands formed on an upper surface of a first circuit board and lands formed on the lower surface of a second circuit board. A temperature controlled bar that includes one or more heating elements places pressure on the joint between the two printed circuit boards while producing sufficient heat to cause the solder to reflow between the lands on the first PCB and the second PCB. The temperature controlled bar releases pressure on the joint after reflowing the solder.

### SUMMARY

Electronic device enclosures provide a challenging environment for designers. This is particularly true for devices in which multiple printed circuit boards may be connected using flexible connectors or devices that rely on one or more flexible printed circuit boards. Traditionally, such boards were communicatively coupled using pins and connectors or similar physical attachment features. However, with greater emphasis being placed on smaller, extremely thin, aesthetically pleasing devices, often sufficient space (or height) does not exist within smaller and/or thinner enclosures to permit the use of such traditional physical connection means such as pins, sockets, and/or connectors. In such instances, circuit boards on flexible substrates are used to connect different printed circuit boards using soldered connections.

Cold-bar soldering is useful for conductively coupling printed circuit boards in application where the printed circuit boards are moving relative to each other and/or mechanical coupling of the printed circuit boards is undesirable in terms of tolerance stack and/or performance drop. Such cold-bar solder connections can replace traditional connectors in applications having a suitable number of circuits (e.g., between 1 and 32 circuits).

Cold-bar soldering is used to form a physical and conductive coupling between a flexible circuit board (FCB) and a rigid or semi-rigid printed circuit board (PCB). The FCB is formed using a flexible substrate having a first surface and a second surface transversely opposed across the thickness of the FCB to the first surface. The FCB includes one or more pads disposed on at least a portion of the first surface of the flexible substrate and one or more heating elements formed on at least a portion of the second surface of the FCB. The portion of the second FCB surface that includes the one or more heating elements at least partially overlaps the portion of the first FCB surface that includes the one or more pads.

The one or more heating elements include one or more connectors to permit the conductive coupling of a controlled output, external, power supply subsystem to the one or more heating elements. The power supply subsystem may generate a controlled voltage output to adjust the current flow through, and consequently the surface temperature, of each of the one or more heating elements. The one or more heating elements produce and emit sufficient thermal energy to melt, liquefy, and/or reflow solder disposed between the one or more FCB pads and respective ones of the one or more PCB lands. The one or more heating elements remain affixed to the second surface of the FCB after disconnection of the external power supply subsystem.

An illustrative cold-bar solder system includes a platform to hold the FCB and PCB such that one or more FCB pads align with the one or more PCB lands, a controllable output, external, power supply subsystem, and an external pressure application system to exert an external pressure force on at least the portion of the FCB that includes the one or more pads. The cold-bar solder system may further include a control system coupled to the power supply and the pressure application subsystems, one or more sensors, and one or more control devices variety of sensors. The cold-bar solder system may further include one or more storage devices that include machine readable and/or machine executable instructions that when executed by the control system, cause the control system to perform the cold-bar solder process.

An illustrative cold-bar solder process includes first positioning the FCB and PCB on the platform with solder disposed between the one or more FCB pads and the one or more PCB lands. The cold-bar solder process commences with the control system causing the conductive coupling of the external power supply subsystem to the one or more heating elements via the one or more connections. The control system may further cause the pressure application subsystem to preload to a defined pressure at least the portion of the FCB that includes the one or more pads.

The cold-bar soldering process occurs over a sequence of intervals. Over a first interval, the control system can first measure the resistance of the one or more heating elements. Over a second interval, the control system can cause the power supply subsystem to apply a voltage that causes a current flow sufficient to heat the one or more heating elements to an operating temperature based on the measured resistance of the one or more heating elements. Over a third interval, the control system can cause the power supply subsystem to maintain the operating temperature of the one or more heating elements at a level sufficient to reflow the solder between the one or more FCB pads and the one or more PCB lands. Over a fourth and final interval, the control system can cause the power supply subsystem to interrupt the voltage supply to the one or more heating elements and cause the pressure application subsystem to maintain pressure on the stacked FCB and PCB as the solder cools, solidifies, and conductively couples the FCB to the PCB. As the conductively coupled FCB/PCB system cools, the control system can directly or indirectly monitor the temperature of the FCB/PCB system, for example by measuring the resistance of the solder joint between the FCB and PCB. External cooling may be applied to further cool the soldered connection between the FCB and PCB. The total cold-bar solder cycle time to complete the aforementioned sequence of intervals typically ranges from about 5 seconds to about 20 seconds.

### BRIEF DESCRIPTION OF THE DRAWINGS

FIG. 1A is a plan view of a first surface of an illustrative flexible circuit board (FCB) that depicts one or more illustrative pads disposed on a portion of the first side of the FCB, in accordance with one or more embodiments described herein.

FIG. 1B is a plan view of a second surface of the illustrative FCB depicted in FIG. 1A that depicts one or more illustrative heating elements disposed on a portion of the second side of the FCB, in accordance with one or more embodiments described herein.

FIG. 1C is a composite plan view of the illustrative FCB in FIGS. 1A and 1B that depicts the overlayment of the one or more heating elements over the one or more pads, in accordance with one or more embodiments described herein.

FIG. 1D is a cross-sectional elevation of the illustrative FCB depicted in FIGS. 1A-1C, along sectional line D-D, in accordance with one or more embodiments described herein.

FIG. 2A is a plan view of a surface of an illustrative printed circuit board (PCB) having one or more illustrative lands disposed on a portion of the surface with solder prepositioned on each of the one or more lands, in accordance with one or more embodiments described herein.

FIG. 2B is a plan view of another illustrative PCB configuration that includes one or more illustrative lands disposed in two parallel linear rows on the surface of substrate with solder prepositioned on each of the one or more lands, in accordance with one or more embodiments described herein.

FIG. 2C is a plan view of yet another illustrative PCB configuration that includes one or more illustrative lands disposed radially about a center point of a circular or semi-circular substrate with solder prepositioned on each of the one or more lands, in accordance with one or more embodiments described herein.

FIG. 2D is a cross-sectional elevation of the illustrative printed circuit board depicted in FIG. 2A along sectional line D-D, in accordance with one or more embodiments described herein.

FIG. 3A is an elevation of an illustrative cold-bar soldering system that depicts an FCB and a PCB stacked and positioned on a platform preparatory to commencing the cold-solder process, in accordance with one or more embodiments described herein.

FIG. 3B is an elevation of the illustrative cold-bar soldering system depicted in FIG. 3A that depicts a pressure application subsystem applying a preload pressure to the stacked FCB and PCB, in accordance with one or more embodiments described herein.

FIG. 3C is an elevation of the illustrative cold-bar soldering system depicted in FIGS. 3A and 3B that depicts a power supply subsystem connected to the one or more heating elements disposed on the FCB, in accordance with one or more embodiments described herein.

FIG. 3D is an elevation of the illustrative cold-bar soldering system depicted in FIGS. 3A-3C that depicts the power supply subsystem providing a voltage output to the one or more heating elements, in accordance with one or more embodiments described herein.

FIG. 3E is an elevation of the illustrative cold-bar soldering system depicted in FIGS. 3A-3D that depicts the physically and conductively coupled FCB and PCB after removal of the power supply subsystem and the pressure application subsystem, in accordance with one or more embodiments described herein.

FIG. 4 is a chart depicting electrical and thermal parameters over the course of an illustrative cold-bar solder cycle using a system such as depicted in FIGS. 3A-3E, in accordance with one or more embodiments described herein.

FIG. 5 is a chart depicting electrical and thermal parameters over the course of another illustrative cold-bar solder cycle, in accordance with one or more embodiments described herein.

FIG. 5 is a flow diagram of an illustrative cold-bar solder cycle using a system such as depicted in FIGS. 3A-3E, in accordance with one or more embodiments described herein.

### DETAILED DESCRIPTION

In contrast to more traditional hot-bar soldering techniques, a cold-bar soldering technique does not require the application of heat using a high temperature external device. Instead, the cold-bar soldering technique uses one or more heating elements disposed on a first circuit board (“FCB”) to provide thermal energy in the form of heat to the solder joint between one or more pads disposed on the surface of a first circuit board and one or more corresponding pads disposed on the surface of a second circuit. As described herein, the first circuit board can include a flexible circuit board (“FCB”), such as those typically used to connect a printed circuit board (“PCB”) to another device. The FCB can include one or more pads disposed on a first surface that are conductively coupled to a corresponding number of one or more lands disposed on the surface of the PCB. One or more heating elements can be disposed on a second surface of the FCB that is transversely opposed across a thickness of the FCB to the one or more pads on the first surface of the FCB.

Solder in the form of solid solder or a solder paste is disposed on at least one of the one or more pads on the FCB or the one or more lands on the PCB. The FCB and PCB are stacked on a platform such that the solid solder or solder paste is disposed between the one or more pads on the first surface of the FCB and corresponding ones of the one or more lands on the surface of the PCB. A pressure application subsystem provides a continuous fixed or variable pressure to the stacked FCB/PCB system to maintain alignment of the FCB and the PCB during the cold-bar soldering process. An external power supply subsystem couples to the one or more heating elements on the second surface of the FCB using connections disposed on the FCB.

Since each FCB includes one or more heating elements, board-to-board differences within an allowable, defined, manufacturing tolerance will occur. Since the thermal energy produced by the one or more heating elements is dependent on the resistance of the one or more heating elements, the cold-bar soldering system performs an initial determination of the resistance of the one or more heating elements on the FCB over a first interval. The cold-bar soldering system may perform periodic, intermittent, aperiodic, or randomly spaced heating element resistance measurements throughout all or a portion of the cold-bar soldering process.

The cold-bar soldering process can be broken into a number of intervals after the FCB is stacked on the PCB, trapping the solid solder or solder paste between the one or more pads on the FCB and the one or more lands on the PCB. During a first interval, a control system can cause the pressure application subsystem to apply a preload pressure to the stacked FCB/PCB system. The control system then conductively couples an external, variable output, controllable, power supply subsystem to the one or more heating elements. After preloading the stacked FCB/PCB system, the control system measures or otherwise determines the resistance of the one or more heating elements disposed on the second surface of the FCB. The control system can obtain the resistance of the one or more heating elements via the power supply subsystem.

Over a second interval, the control system causes the power supply subsystem to apply a voltage to the one or more heating elements. The applied voltage is sufficient to cause the temperature of the one or more heating elements to increase to a level sufficient to cause the solder disposed between the FCB and the PCB to reflow. The control system can cause the power supply subsystem to increase the temperature of the one or more heating elements over a second interval having a duration of a few seconds or less.

Over a third interval, the control system causes the power supply subsystem to maintain the voltage to the one or more heating elements for a length of time sufficient to cause the reflow of the solder between each of the one or more pads on the first surface of the FCB and corresponding ones of the one or more lands on the surface of the PCB. The control system can cause the power supply subsystem to maintain the temperature of the one or more heating elements at a defined operating temperature, such as a temperature of about 60° C. to about 80° C. above the melting point of the solder, for third interval having a duration of several seconds.

Over a fourth interval, the control system causes the power supply subsystem to cease providing a voltage to the one or more heating elements while causing the pressure application subsystem to maintain an external pressure on the FCB/PCB system. The control system causes the pressure application subsystem to maintain pressure on the FCB/PCB system until the reflowed solder is solidified and the conductive coupling between the FCB and PCB is established. The control system may determine or otherwise measure the temperature of the solder connection(s) between the pads on the FCB and the lands on the PCB based on a measured resistance value.

As used herein the term “about” when used in the context of a value or numeric value should be understood to mean the indicated numeric value may vary from the recited value by up to plus or minus 10%. For example, the statement “a temperature of about 200° C.” should be understood to include any temperature in the range of 200° C. minus 10 % (i.e., 200° C.−20° C.=180° C.) to 200° C. plus 10% (i.e., 200° C.+20° C.=220° C.).

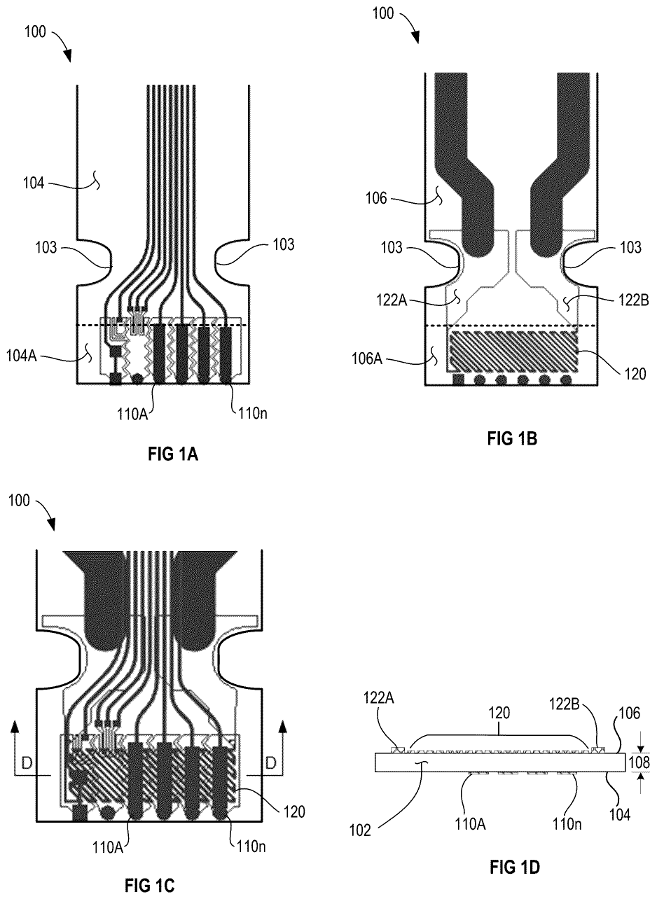

FIGS. 1A-1D depict an illustrative flexible circuit board (FCB) 100 that includes one or more pads 110 disposed in a portion 104A of a first surface 104 of a flexible substrate 102 and one or more heating elements 120 disposed on a portion 106A of a second surface 106 of the flexible substrate 102 transversely opposed across a thickness 108 of the flexible substrate 102 to the portion 104A, in accordance with one or more embodiments described herein. FIG. 1A depicts a plan view of one or more pads 110A-110n (collectively, “pads 110”) disposed on a portion 104A a first surface 104 of a flexible substrate 102. FIG. 1B depicts a plan view of one or more heating elements 120 disposed on a portion 106A of a second surface 106 of the flexible substrate 102 depicted in FIG. 1A. FIG. 1C depicts the positioning of the one or more pads 110A-110n with respect to the one or more heating elements 120. FIG. 1D depicts a cross-sectional elevation of the illustrative FCB 100 depicted in FIGS. 1A and 1B along sectional line D-D. Flexible circuit boards, such as the FCB 100 depicted in FIGS. 1A-1D may be used, for example, to conductively couple circuit boards disposed within an electrical device. The FCB 100 depicted in FIGS. 1A-1D, permits the physical and electrical coupling of nested or closely stacked rigid and/or semi-rigid printed circuit boards advantageously improving the performance and/or aesthetics of electronic devices.

FIG. 1A depicts an FCB 100 that includes a substrate 102 having a first surface 104 that includes one or more pads 110 or similar exposed conductive elements disposed in at least one portion 104A of the first surface 104. As depicted in FIG. 1A, the substrate 102 includes one or more apertures, notches, cutouts, voids, or other similar alignment features 103 to assist in aligning the FCB 100 with or stacking the FCB 100 on a printed circuit board (PCB) in a cold-bar solder process. Although a semicircular cutout 103 is depicted in FIG. 1A, the cutout 103 can have any shape, for example a rounded square cutout. Similarly, the cutout 103 may include a round, oval, or polygonal cutout or aperture formed in the substrate 102. The substrate 102 may include a single-or a multi-layer substrate. Circuitry in the form of conductive traces and/or electronic components may be disposed in, on, or about the first surface 104 of the FCB substrate 102. A protective or insulative coating (not depicted in FIG. 1A) may cover all or a portion of the first surface 104. In embodiments, the substrate 102 includes one or more of a polyimide film, a polyester film, a polyethylene film, a glass fiber film, or similar flexible, electrically insulative or dielectric material.

The first portion 104A of the first surface 104 of the substrate 102 includes one or more pads 110A-110n (collectively, “pads 110”) printed, plated, deposited, or otherwise formed therein. In at least some instances, the one or more pads 110 are formed along all or a portion of an edge of the substrate 102, such as depicted in FIG. 1A. The one or more pads 110 may be formed using one or more electrically conductive materials, such as copper, aluminum, silver, or alloys thereof. In some embodiments, the one or more pads 110 includes a plurality of pads 110 may be disposed along all or a portion of two or more edges of the first portion 104A of the first surface 104 of the substrate 102. In operation, the one or more pads 110 provide a conductive pathway that permits the electrical and physical coupling of the FCB 100 to an external device such as a PCB, input/output components, user interface components, sensor components, or combinations thereof. In embodiments, the one or more pads 110 include a plurality of pads 110A-110n arranged linearly to form a single row along an edge of the substrate 102. Although not depicted in FIG. 1A, one of ordinary skill in the art will recognize the one or more pads 110 may be arranged in a virtually unlimited number of geometries, arrangements, or configurations. In one example, the one or more pads 110 include a plurality of pads 110A-110n arranged radially about a circular or semi-circular substrate 102. In another example, the one or more pads 110 include a plurality of pads 110A-110n arranged linearly to form two parallel rows along an edge of the substrate 102.

Each of the one or more pads 110 may have any physical geometry, shape, thickness, and/or configuration. For example, each of the one or more pads 110 may have a rectangular geometry having a width of: about 0.5 millimeters (mm) or less; about 1 mm or less; about 2 mm or less; about 3 mm or less; or about 5 mm or less. The one or more pads 110 may be evenly or unevenly spaced or distributed along one or more edges of the substrate 102. For example, the one or more pads 110 may include a plurality of pads spaced at a pitch of: about 0.25 millimeters (mm) or less; about 0.5 mm or less; about 1 mm or less; or about 2 mm or less. Each of the one or more pads 110 may have the same or different thicknesses. For example, in some embodiments, each of the one or more pads may have the same thickness of from about 10 microns (μm) to about 30 microns (μm). In embodiments, some or all of the pads 110 may have an aperture formed therethrough to confirm solder reflow.

FIG. 1B depicts one or more illustrative heating elements 120 disposed in a portion 106A of the second surface 106 of the flexible substrate 102. The second surface 106 is transversely opposed across a thickness 108 of the flexible substrate 102 to the first surface 104. In at least some embodiments, the portion 106A of the second surface 106 aligns, overlays, overlaps, or is superimposed at least in part, with the portion 104A of the first surface 104. Each of the one or more heating elements 120 include connections 122A-122n to enable the conductive coupling of an external power supply subsystem to the respective heating element 120.

In embodiments where the FCB 100 includes a plurality of pads 110, each of the one or more heating elements 120 overlays at least two (and often more) of the plurality of pads 110. Overlapping each of the heating elements 120 across two or more pads 110 beneficially facilitates an even distribution of heat produced by the heating element 120 across each of the two or more pads 110, thereby improving the uniformity of heating across each of the plurality of pads 110 improving the consistency of solder reflow across each of the plurality of pads 110A-110n.

Upon application of a voltage to each of the one or more heating elements 120, current flowing through the respective heating element 120 produces an emission of thermal energy (i.e., heat) by the respective heating element 120. The magnitude of the thermal energy produced and emitted by each of the one or more heating elements 120 is proportional to the resistance or impedance of the respective heating element 120, the applied voltage and/or the current flowing through the respective heating element 120. Since the thermal energy production and/or operating temperature of each of the one or more heating elements 120 is a function of the current flowing through the heating element 120, the operating temperature of each of the one or more heating elements 120 may be adjusted, altered, or otherwise controlled by adjusting, altering, changing, or otherwise controlling the current passing through the respective heating element 120. The resistance of each of the one or more heating elements 120, and consequently the thermal energy produced by the respective heating element 120, is dependent upon the conductivity of the material used to form the respective heating element 120 as well as the physical properties of the respective heating element 120, such as length and cross sectional area. Ordinary manufacturing tolerances result in a variance in the resistance of each of the one or more heating elements 120 on each FCB 100. Since the thermal energy production and/or operating temperature of each of the one or more heating elements 120 is related to the applied voltage and/or current flow through the respective heating element 120 and the current flow is dependent on the resistance or impedance of the respective heating element 120, the resistance of the heating element 120 may be determined at least once prior to commencing the cold-bar solder process.

The resistance of the one or more heating elements 120 may change or vary with the operating temperature of the one or more heating elements 120. For example, the resistance of the one or more heating elements 120 may increase as the operating temperature of the one or more heating elements 120 increases. To compensate for this potential change in resistance of the one or more heating elements 120, a cold-bar soldering controller may calculate, measure, detect, or otherwise determine the resistance of the one or more heating elements 120 on a periodic or aperiodic basis throughout all or a portion of the cold-bar soldering process. Further, the cold-bar soldering controller may control, alter, or otherwise adjust one or more output parameters of a power supply subsystem, such as an output voltage provided to the one or more heating elements 120, at one or more points during the cold-bar soldering process. The cold-bar soldering controller may control, alter, or otherwise adjust the output parameters of the power supply subsystem based, at least in part, on the determined resistance and/or change in resistance of the one or more heating elements 120 at the one or more points during the cold-bar soldering process.

At least a portion of the thermal energy produced or emitted by each of the one or more heating elements 120 passes through the flexible substrate 102, increasing the temperature of the pads 110 that overlay the one or more heating elements 120. The thermal energy produced by the one or more heating elements 120 and reaching the one or more pads 110 is sufficient to cause solder disposed proximate the one or more pads 110 to melt, liquefy, and/or reflow. Since the operating temperature of the heating element is a function of the current (i.e., a function of the voltage applied across the heating element 120 and the resistance of the heating element 120) passed through the heating element 120, the operating temperature of the heating element 120 may be adjusted, altered, or otherwise controlled by adjusting, altering, changing, or otherwise controlling the applied voltage and/or current flow through the one or more heating elements 120. The resistance of the one or more heating elements 120, and consequently the thermal energy produced by the one or more heating elements 120, is dependent upon the conductivity of the material used to form the one or more heating elements 120 as well as the physical properties of the one or more heating elements 120, such as length and cross sectional area.

FIG. 1C is a plan view that depicts an illustrative arrangement in which the one or more pads 110 overlay the one or more heating elements 120. As depicted in FIG. 1C, each of the one or more heating elements 120 is disposed in portion 106A of the second surface 106 in a location that corresponds to a portion of each of the one or more pads 110 disposed in portion 104A of the first surface 104. In the embodiment depicted in FIG. 1C, the one or more heating elements 120 include a plurality of serpentine conductors arranged diagonally, each of which span two or more pads 110 disposed on the first surface 104. Other conductor arrangements are possible, for example serpentine lateral conductors or serpentine longitudinal conductors. In yet other arrangements, combinations of diagonal, lateral, and/or longitudinal conductors may be used to ensure an even distribution of heat across the one or more pads 110. In some embodiments, such as the embodiment depicted in FIGS. 1A and 1B, the area occupied by the one or more pads 110 on the first surface 104 of the substrate extends beyond the area occupied by the one or more heating elements 120 on the second surface 106 of the substrate 102. In other embodiments, the area occupied by the one or more pads 110 on the first surface 104 of the substrate approximately equals the area occupied by the one or more heating elements 120 on the second surface 106 of the substrate 102.

FIG. 1D depicts a cross-sectional view of the illustrative flexible circuit board 100 depicted in FIGS. 1A-1C. The transverse thickness 108 of the flexible substrate 102 separates the one or more heating elements 120 disposed on the second surface 106 of the substrate 102 from the one or more pads 110 disposed on the first surface 104 of the substrate 102. In some embodiments the flexible substrate 102 can have a thickness 108 of from about 0.001 inches to about 0.010 inches. Thermal energy produced by the one or more heating elements 120 passes through the flexible substrate 102, increasing the temperature of the one or more pads 110. The thermal energy emitted by the one or more heating elements 120 increases the temperature of the one or more pads 110 sufficient to liquefy solder in contact with the one or more pads 110.

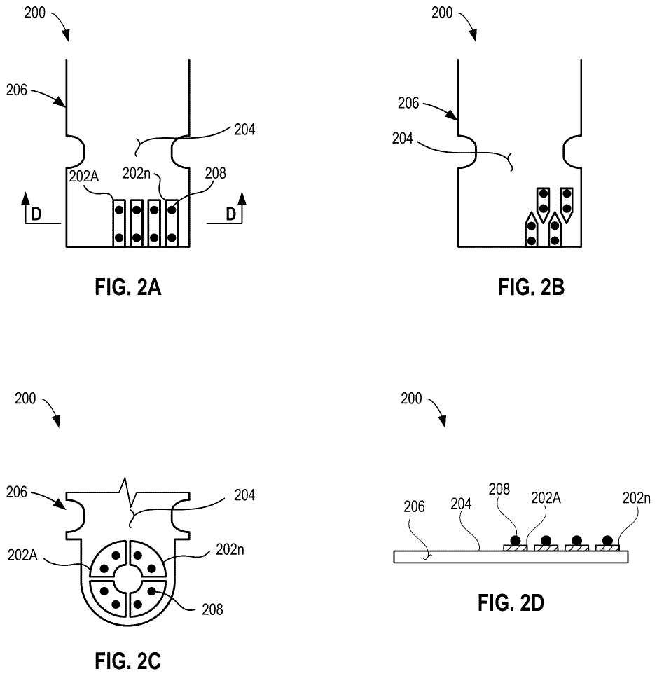

FIG. 2A depicts an illustrative printed circuit board (“PCB”) 200 that includes one or more lands 202A-202n (collectively, “lands 202”) disposed on a surface 204 of a substrate 206. All or a portion of the one or more lands 202 disposed on the PCB 200 are positioned to align with all or a portion of the one or more pads 120 disposed on the surface 104 of the flexible circuit board 100. Each of the one or more lands 202 includes a portion of solder or solder paste, deposited on the surface of some or all of the one or more lands 202. In embodiments, each of the one or more lands 202 includes solid solder deposited at a density of: from about 0.035 mm³ solder per mm² of land area (mm³/mm² land area) to about 0.100 mm³/mm² land area; from about 0.050 mm³/mm² land area to about 0.095 mm³/mm² land area; from about 0.065 mm³/mm² land area to about 0.090 mm³/mm² land area; or from about 0.075 mm³/mm² land area to about 0.090 mm³/mm² land area. In embodiments, each of the one or more lands 202 includes solder paste deposited at a density of: from about 0.070 mm3 solder per mm² of land area (mm³/mm² land area) to about 0.200 mm³/mm² land area; from about 0.100 mm³/mm² land area to about 0.190 mm³/mm² land area; from about 0.130 mm³/mm² land area to about 0.180 mm³/mm² land area; or from about 0.150 mm³/mm² land area to about 0.180 mm³/mm² land area.

FIG. 2B is a plan view of another illustrative PCB 200 configuration that includes one or more lands 202A-202n disposed in two parallel linear rows on the surface 204 of substrate 206 in accordance with one or more embodiments described herein. As depicted in FIG. 2B, the one or more lands 202 may be disposed in a plurality of rows arranged parallel to the edge of the substrate 206.

FIG. 2C is a plan view of yet another illustrative PCB 200 configuration that includes one or more lands 202 disposed radially about a center point of a circular or semi-circular substrate 206 in accordance with one or more embodiments described herein. As depicted in FIG. 2C, the one or more lands 202 may be disposed as one or more “pie shaped” sections disposed radially about a center point on the substrate 206.

FIG. 2D depicts a cross-section of the illustrative printed circuit board 200 depicted in FIG. 2A along sectional line D-D. Solder 208 is disposed on each of the one or more lands 202. The solder 206 may include any number, type, and/or combination of solder, solder paste, and/or flux. The solder 206 can have any melting point and/or melting point range. The solder 206 can have a melting point range of: about 180° C. to about 260° C.; about 190° C. to about 250° C.; about 200° C. to about 240° C.; about 200° C. to about 230° C.; or about 200° C. to about 225° C. For example, in some embodiments, an SAC305 solder having a melting range of 217° C. to about 219° C. may be deposited on some or all of the one or more lands 202. For clarity and conciseness, solder 208 is disclosed herein as being disposed on the one or more lands 202. However, it should be understood that solder 208 may be disposed with equal efficiency and effectiveness on some or all of the one or more pads 110 disposed on the surface 104 of FCB 100. For example, solder paste may be used in lieu of solid solder, and the solder paste may be disposed on the one or more pads 110 disposed on the surface 104 of FCB 100 rather than on the one or more lands disposed on the surface 204 of PCB 200.

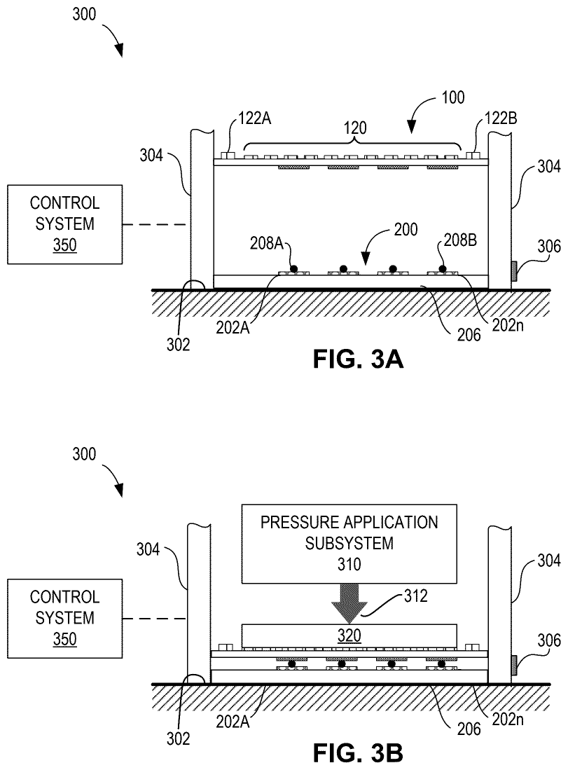

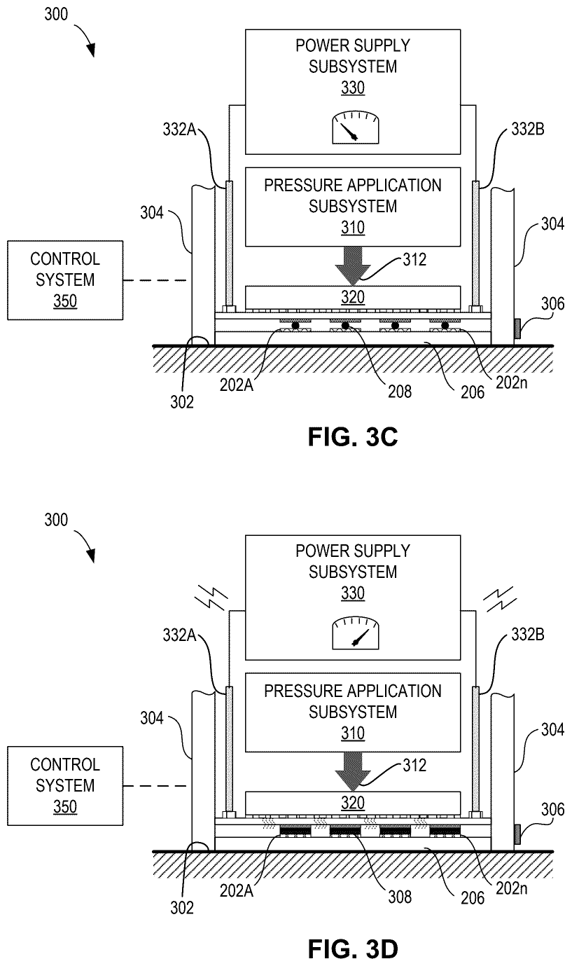

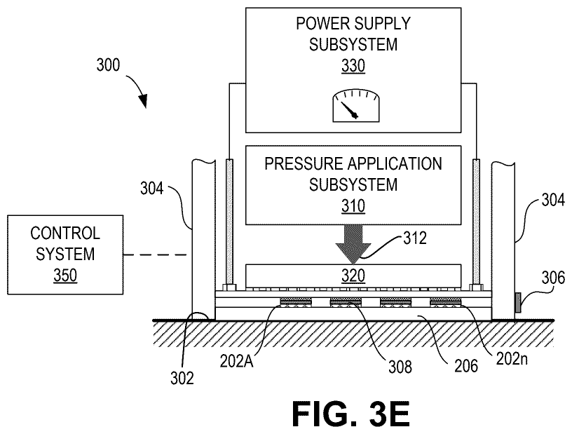

FIGS. 3A-3E depict an illustrative system 300 including a control system 350 configured to cold-bar solder a flexible circuit board (FCB) 100 to a printed circuit board (PCB) 200 using the illustrative cold-bar soldering technique disclosed herein. FIG. 3A depicts a PCB 200 disposed on a platform 302 between alignment members 304A and 304B (collectively, “alignment members 304”). As depicted in FIG. 3A, solder 208 has been disposed on each of one or more lands 202A-202n on the surface 204 of PCB 200. A FCB 100 is also disposed between alignment members 304A and 304B. The alignment members 304A and 340B facilitate or otherwise permit the alignment and/or coordination of the one or more pads 110A-110n disposed on the first surface 104 of the FCB 100 with respective corresponding ones of the one or more lands 202A-202n on the disposed on the surface 204 of the PCB 200. The alignment members 304 can include a rigid member having any shape and/or surface treatment that permits and/or facilitates the displacement of the PCB 200 and/or the FCB 100 along the surface of each of the alignment members 304. Although two alignment members are depicted in FIGS. 3A-3E, any number of alignment members 304 may be used with similar efficiency and effectiveness. In embodiments, one or more sensors such as one or more optical sensors and/or one or more proximity sensors 306 may provide a signal that includes information indicative of a proper positioning of the FCB 100 with respect to the PCB 200 as an input to a control system 350.

In FIG. 3B the control system 350 causes a pressure application subsystem 310 to apply pressure 312 to all or a portion of the second surface 106 of the FCB 100. The pressure application subsystem 310 may apply some or all of the pressure to a rigid member 320 disposed proximate the FCB 100. Application of pressure to the rigid member 320 beneficially maintains a generally constant pressure across at least the portion 104A of the first surface 104 of the flexible substrate 102 containing the one or more pads 110. The pressure application subsystem 310 includes one or more pneumatic, hydraulic, and/or electro-hydraulic systems capable of providing a linear, compressive, force 312 to the stacked FCB 100 and PCB 200. The control system 350 causes the pressure application subsystem 310 to apply a pressure 312 the FCB 100 and PCB 200 of: about 60 psig or less; about 80 psig or less; about 100 psig or less; or about 120 psig or less. In embodiments, the rigid member 320 can include any number and or combination of electrically insulative materials, such as one or more rigid FRP circuit boards. In embodiments, the rigid member 320 can include one or more thermally insulative materials to reduce environmental heat losses as the temperature of the heating element 120 increases. In embodiments, the control system 350 receives one or more input signals indicative of the pressure 312 applied to the FCB 100 and the PCB 200 by the pressure application subsystem 310.

In FIG. 3C, the control system 350 conductively couples the heating element 120 to a power supply 330 by causing a plurality electrodes 332A and 332B (collectively, “electrodes 332”) to conductively couple to the heating element connections 122. In embodiments, the control system 350 alters, adjusts, or otherwise controls one or more output parameters, such as voltage or current, of the power supply subsystem 330 to maintain the one or more heating elements 120 at a defined operating temperature and/or within a defined operating temperature range. Beneficially, the ability to control, alter, or adjust the temperature of the heating element 120 facilitates the use of solders and/or solder pastes having different melting points and/or the use of different flexible substrates 102. The control system 350 adjusts the operating temperature of the heating element 120 based on the melting point of solder 208. In embodiments, the control system 350 adjusts one or more power supply subsystem output parameters to maintain the operating temperature of the one or more heating elements 120 at a defined operating temperature or within a defined operating temperature range. In embodiments, the control system 350 maintains the one or more heating elements 120 at an operating temperature defined by the melting point of the solder 208, allowing for thermal losses through the flexible substrate 102 and thermal losses at the surface of the one or more heating elements 120. In embodiments, the control system 350 can maintain the one or more heating elements 120 at a temperature of: about 50° C. greater than the melting point of the solder 208; about 65° C. greater than the melting point of the solder 208; about 80° C. greater than the melting point of the solder 208; or about 95° C. greater than the melting point of the solder 208.

In at least some embodiments, the control system 350 controls the variable output voltage of the power supply subsystem 330. Since the operating temperature of the one or more heating elements 120 is based, at least in part, on the current flow through the one or more heating elements 120, the control system 350 can calculate, measure, determine, or otherwise obtain the resistance of the one or more heating elements 120. The control system 350 can then use the determined or measured resistance of the one or more heating elements 120 and the output voltage of the power supply subsystem 330 to determine the current flow through (and consequently the approximate operating temperature of) the one or more heating elements 120. In embodiments, the control system 350 can include memory circuitry to store or otherwise retain data representative of the relationship between current and operating temperature of the one or more heating elements 120. In embodiments, the control system 350 can include memory circuitry to store or otherwise retain data representative of the relationship between the output voltage of the power supply subsystem 330 and operating temperature of the one or more heating elements 120.

The control system 350 can calculate, measure, determine, or otherwise obtain the resistance of the one or more heating elements 120 at any point, or even at multiple points, during the cold-bar soldering process. For example, the control system 350 can calculate, measure, determine, or otherwise obtain the resistance of the one or more heating elements 120 prior to commencement of the cold-bar soldering process. In another example, the control system 350 can calculate, measure, determine, or otherwise obtain the resistance of the one or more heating elements 120 at regular or irregular intervals throughout some or all of the cold-bar soldering process. The control system 350 can use the determined resistance of the one or more heating elements 120 to initially set and/or continuously adjust one or more output parameters of the power supply subsystem 330

In FIG. 3D, the control system 350 causes the power supply 330 to apply a voltage across the one or more heating elements 120 while causing the pressure application subsystem 310 to apply pressure to the FCB 100 and the PCB 200 to cause the solder 208 to reflow 308 thereby conductively coupling the one or more pads 110 on the FCB to the one or more lands 202 on the PCB. In embodiments, the control system 350 receives current and/or voltage feedback signals from the power supply subsystem 330 and uses the received feedback signals to control at least one of the voltage across and/or the current supplied to the one or more heating elements 120. For example, the control system 350 can cause the power supply subsystem 330 to adjust the voltage across the one or more heating elements 120 such that the current through the one or more heating elements 120 maintains or follows a defined thermal profile. In at least some implementations, the control system 350 employs closed-loop control of the output parameter of the power supply subsystem 330 to maintain a defined operating temperature of the one or more heating elements 120.

In at least some embodiments, the control system 350 controls the output voltage of the power supply subsystem 330 such that the one or more heating elements 120 produce an overall thermal output of: about 0.5 watts/mm² of pad area (W/mm²) or greater; about 0.75 W/mm² of pad area or greater; about 1.00 W/mm² of pad area or greater; about 1.50 W/mm² of pad area or greater; or about 2.00 W/mm² of pad area or greater. In other embodiments, the control system 350 controls the output voltage of the power supply subsystem 330 such that the one or more heating elements 120 produce a thermal output in a range of: from about 0.25 watts/mm² of pad area W/mm²) to about 4.00 W/mm² of pad area; from about 0.25 W/mm² of pad area to about 3.00 W/mm² of pad area; from about 0.25 W/mm² of pad area to about 2.50 W/mm² of pad area; from about 0.25 W/mm² of pad area to about 2.00 W/mm² of pad area; or from about 0.50 W/mm² of pad area to about 2.00 W/mm² of pad area.

In embodiments, the power supply subsystem 330 provides a controlled direct current (DC) voltage output to the one or more heating elements 120. The control system 350 can cause the power supply subsystem 330 to provide a DC voltage to the one or more heating elements 120 within a range of: from about 0 VDC to about 30 VDC; from about 0 VDC to about 25 VDC; from about 0 VDC to about 20 VDC; or from about 0 VDC to about 15 VDC. In at least some embodiments, the control system 350 may cause the power supply subsystem 330 to drive the heating element 120 through a defined reflow heating cycle that includes some or all of: an initial heating element resistance determination period (i.e., a first interval or period); an operating temperature ramp period (i.e., a second interval or period); a reflow period (i.e., a third interval or period); and a cooling period (i.e., a fourth interval or period). The initial heating element resistance determination period (i.e., the first interval or period) has a duration of: about 5 seconds or less; about 3 seconds or less; or about 1 second or less. The operating temperature ramp period (i.e., the second interval or period) has a duration of: about 8 seconds or less; about 6 seconds or less; about 4 seconds or less; or about 2 second or less. The reflow period (i.e., the third interval or period) has a duration of: about 8 seconds or less; about 6 seconds or less; about 4 seconds or less; or about 2 second or less. The cooling period (i.e., the fourth interval or period) has a duration of: about 10 seconds or less; about 8 seconds or less; about 6 seconds or less; or about 4 seconds or less. In embodiments, the cold-bar soldering can have a complete cycle time of: about 20 seconds or less; about 15 seconds or less; about 10 seconds or less; or about 8 seconds or less.

In FIG. 3E, the control system 350 causes the pressure application subsystem 310 to maintain the pressure on the FCB 100 as the reflowed solder solidifies. The control system 350 further causes the power supply subsystem 330 to reduce the voltage supplied to the one or more heating elements 120, in accordance with one or more embodiments described herein. In some embodiments, the control system 350 causes the power supply subsystem 330 to reduce the output voltage to the one or more heating elements 120 to zero volts. The solder 308 physically and conductively couples the one or more pads 110 disposed on the first surface 104 of the FCB 100 to respective ones of the one or more lands 202 on the surface of the PCB 200. The physically and electrically coupled FCB and PCB can be removed from the platform 302 and the cycle repeated.

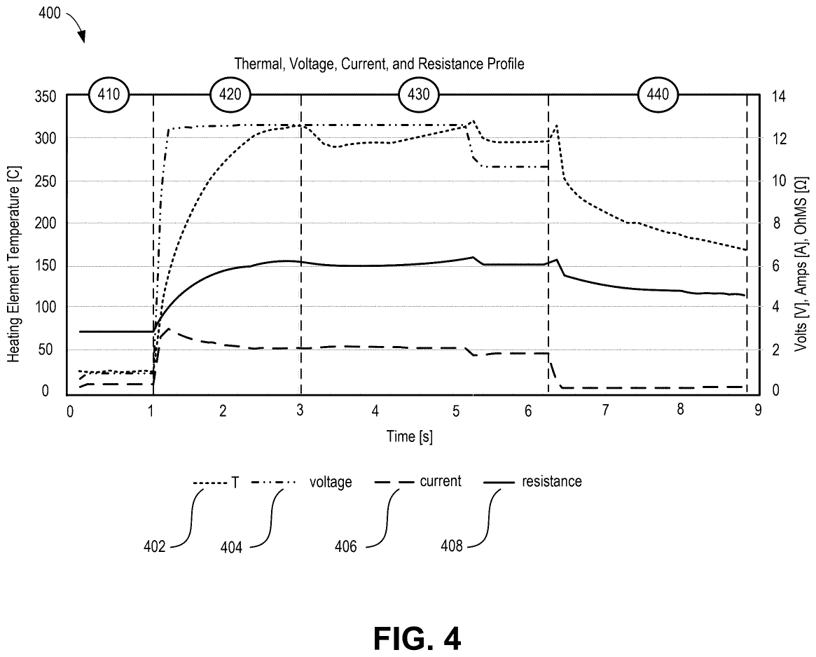

FIG. 4 is a graph that depicts the temperature 402, voltage 404, current 406, and resistance 408 of an illustrative cold-bar soldering cycle 400 in accordance with one or more embodiments described herein. In the illustrative example depicted in FIG. 4, the overall cold-bar soldering cycle 400 has a duration of approximately 10 seconds. The cold-bar soldering cycle includes: a resistance measurement period or interval 410 (i.e., a first interval) during which the control system 350 may measure, sense, detect, calculate, or otherwise determine the resistance or impedance of the one or more heating elements 120. The determination of the resistance of the one or more heating elements 120 permits the control system 350 to adjust the output of the power supply subsystem 330 to compensate for variability in resistance of the one or more heating elements 120. Using an accurate resistance value for the one or more heating elements 120, the control system 350 determines the correct power supply subsystem output voltage and/or current profile to achieve the temperature curve to cause reflow of the solder 208 disposed between the one or more pads 110 on the FCB 100 and the one or more lands 202 on the PCB 200. As depicted in the illustrative embodiment in FIG. 4, the control system 350 can determine the resistance of the one or more heating elements 120 over a first interval 410 having a very short duration of: about 3 seconds or less; about 2 seconds or less; or about 1 second or less.

The illustrative cold bar soldering cycle 400 also includes a second period or interval 420 during which the control system 350 causes one or more output parameters (i.e., the current or voltage) of the power supply subsystem 330 to increase or “ramp”. In at least some embodiments, the control system 350 causes the output voltage 404 of the power supply subsystem 330 to increase to a first voltage value or a first voltage range sufficient to cause the rapid increase in temperature of the one or more heating elements 120 to a defined operating temperature 402. As depicted in the illustrative cold-bar soldering cycle 400, the control system 350 causes the power supply subsystem 330 to quickly increase the voltage 404 to the first voltage value or a first voltage range, causing the temperature of the one or more heating elements 120 to rapidly increase from about 25° C. to about 320° C. in approximately 2 seconds. As depicted in the illustrative embodiment in FIG. 4, the control system 350 causes an adjustment in one or more output parameters of the power supply subsystem 330 to cause an increase the operating temperature 402 of the one or more heating elements 120 to a range of:
from about 240° C. to about 350° C.; from about 250° C. to about 350° C.; from about 275° C. to about 350° C.; or from about 290° C. to about 340° C. As depicted in the illustrative embodiment in FIG. 4, the control system 350 causes an adjustment in one or more output parameters of the power supply subsystem 330 to cause an increase in the temperature of the one or more heating elements 120 to the operating temperature over a second interval 420 having a duration of: about 10 seconds or less; about 8 seconds or less; about 6 seconds or less; about 4 seconds or less; or about 2 seconds or less.

After causing the power supply subsystem 330 to increase the temperature of the heating element 120 to the defined operating temperature, the control system 350 controls, alters, or otherwise adjusts the power supply subsystem 330 to maintain the operating temperature 402 of the one or more heating elements 120 over a third period or interval 430. During the third interval 430, the control system 350 causes the power supply subsystem 330 to maintain the heating element 120 at an operating temperature 402 that causes the transfer of sufficient thermal energy through the FCB 100 to cause the solder 208 disposed between the FCB 100 and the PCB 200 to reflow, thereby physically and conductively coupling the one or more FCB pads 110 to respective ones of the one or more PCB lands 202. In at least some embodiments, the control system 350 causes the power supply subsystem 330 to maintain the first voltage output to maintain the one or more heating elements 120 at the operating temperature. The control system 350 causes an adjustment in one or more output parameters of the power supply subsystem 330 to maintain the one or more heating elements 120 in a temperature range of from: about 250° C. to about 350° C.; about 275° C. to about 350° C.; about 280° C. to about 350° C.; about 290° C. to about 350° C. The control system 350 causes an adjustment in one or more output parameters of the power supply subsystem 330 to maintain the one or more heating elements 120 at the operating temperature for a third interval 430 having a duration of: about 10 seconds or less; about 8 seconds or less; about 6 seconds or less; or about 4 seconds or less.

After heating and reflowing the solder 208, the control system 350 can reduce the voltage output 404 of the power supply subsystem 330 to a second voltage or a second voltage range that is less than the first voltage or the first voltage range at the start of a fourth interval 440. Reducing the voltage applied to the one or more heating elements 120 permits the one or more heating elements to cool, thereby allowing the solder between the one or more pads 110 on the FCB 100 and the one or more lands 202 on the PCB 200 to solidify, physically and conductively coupling the FCB 100 to the PCB 200. In some implementations, the control system 350 can cause the pressure application subsystem 310 to maintain pressure on the FCB/PCB stack for all or a portion of the fourth interval. In some implementations, the control system 350 can cause the power supply subsystem 310 to reduce the output voltage to zero (0) volts (i.e., remove voltage from the one or more heating elements 120). In some implementations, the control system 350 can disconnect the power supply subsystem 330 from the one or more heating elements 120 for all or a portion of the fifth interval 450. The control system 350 causes an adjustment in one or more output parameters of the power supply subsystem 330 to provide the third voltage to the heating element 120 for a fifth interval 450 having a duration of: about 15 seconds or less; about 15 seconds or less; about 10 seconds or less; about 5 seconds or less; or about 3 seconds or less.

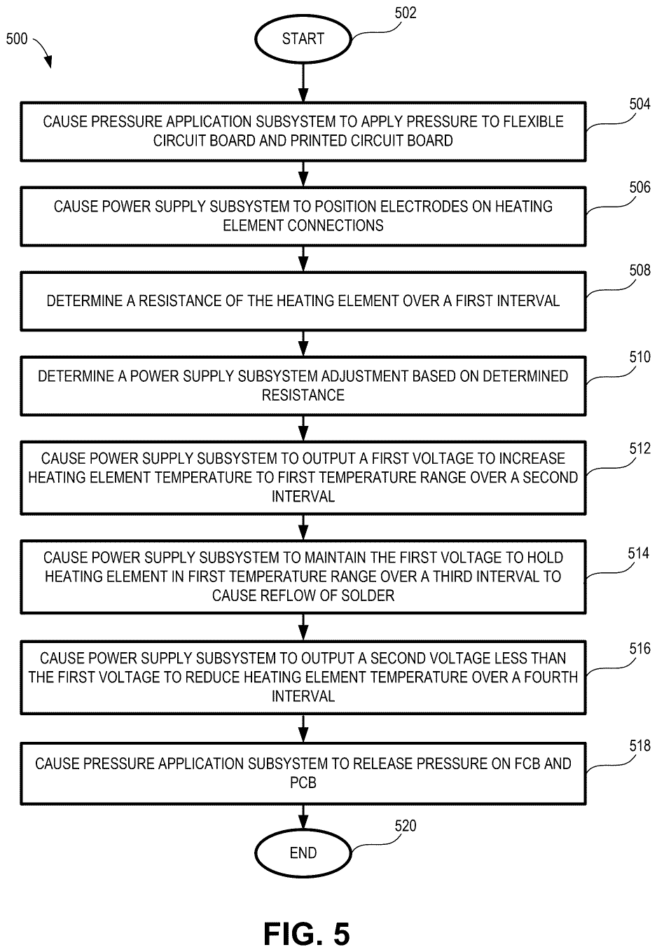

FIG. 5 depicts an illustrative cold-bar solder method 500 to physically and conductively couple one or more pads 110 on a first surface 104A of a flexible circuit board (FCB) 100 to respective ones of one or more lands 202 on a surface of a printed circuit board (PCB) 200 in accordance with one or more embodiments described herein. A cold-bar soldering system capable of performing the method 500 includes a control system 350 communicatively and/or operatively coupled to a power supply subsystem 330. The control system 350 can receive one or more inputs from the power supply subsystem 330 and/or one or more inputs from one or more sensors operatively coupled to the cold-bar soldering system. Such inputs can include, but are not limited to, the current supplied to by the power supply subsystem 330 to the one or more heating elements 120, the voltage supplied to by the power supply subsystem 330 across the one or more heating elements 120, the resistance of the one or more heating elements 120, or combinations thereof. In some embodiments, the control system 350 can control the output of the power supply subsystem 330 via closed-loop control using the operating temperature of the one or more heating elements 120 as a process variable and either or both a measured current and/or a measured voltage provided by the power supply subsystem 330 to the one or more heating elements 120 as the control variable. In at least some implementations, the method 500 may be stored in the form of one or more sets of machine readable instructions in memory circuitry disposed at least partially within or communicatively coupled to the control system 350. The method 500 commences at 502.

At 504, the control system 350 causes a pressure application subsystem 310 to preload an external pressure on the FCB 100 and the PCB 200. The application of external pressure causes solder positioned between the one or more pads 110 on the FCB 100 and corresponding ones of one or more lands on the PCB to contact both the pad on the FCB and the land on the PCB preparatory to reflowing the solder 208. In some implementations, the control system 350 causes the pressure application subsystem 310 to preload the stacked FCB/PCB with a fixed compressive force (i.e., a preload pressure). For example, the control system 350 may cause the pressure application subsystem 310 to maintain a constant pressure on the stacked FCB/PCB within a range of: from about 60 psig to about 120 psig over the duration of the cold-bar soldering process. In other implementations, the control system 350 causes the pressure application subsystem 310 to vary the pressure applied to the stacked FCB/PCB through all or a portion of the cold-bar soldering process. For example, the control system 350 may cause the pressure application subsystem 310 to vary the pressure applied to the stacked FCB/PCB between about 60 psig and about 120 psig over the duration of the cold-bar soldering process. The pressure application subsystem 310 may include a rigid member 320 that spans at least a portion of the second surface 106. The rigid member 320 evenly distributes the pressure applied by the pressure application subsystem 310 to the FCB 100 and PCB 200. In embodiments, the rigid member 320 includes a thermally conductive member and/or one or more thermally conductive layers. The rigid member 320 may include one or more thermally insulative layers. The control system 350 causes the pressure application subsystem 310 to apply a pressure to the stacked FCB/PCB of: about 60 psig or less; about 80 psig or less; about 100 psig or less; or about 120 psig or less.

At 506, the control system 350 causes a power supply subsystem 330 to position electrodes 332 in contact with connections 122 conductively coupled to the heating element 120.

At 508, after the PCB 200 and the FCB 100 are positioned on the platform and aligned using the alignment members 304, the control system 350 determines the resistance or impedance of the heating element 102 over a first interval 410. In at least some implementations, the control system 350 causes the power supply subsystem 330 to apply a known test voltage (e.g. 1 VDC) across the one or more heating elements 120. Using the known test voltage the control system 350 calculates, obtains, measures, or otherwise determines the resistance or impedance of the heating element 120.

At 510, the control system 350 adjusts, compensates, or corrects the output of the power supply subsystem 330 based on the calculated, measured, or determined resistance or impedance of the one or more heating elements 120. The operating temperature of (hence, the thermal energy emitted by) the one or more heating elements 120 is a function of the applied voltage and the resistance of the respective one or more heating elements 120. Ordinary manufacturing variations in the resistance of the one or more heating elements 120 thus may impact either or both the operating temperature and/or the thermal energy emitted by the one or more heating elements 120. Using the measured or determined resistance of the one or more heating elements 120, the control system 350 can compensate for these variances in resistance of the one or more heating elements 120 by causing the power supply subsystem 350 to adjust one or more output parameters to achieve a desired and consistent operating temperature of the one or more heating elements 120.

At 512, the control system 350 causes the power supply subsystem 330 to increase the operating temperature of the one or more heating elements 120 to an elevated temperature in a first temperature range. The increase in heating element temperature occurs over a relatively shorter duration second interval 420. For example, the control system 350 causes the power supply subsystem 330 to increase the one or more heating elements 120 to a temperature between 290° C. and 350° C. over a first interval of about 2 seconds or less. In one embodiment, the control system 350 causes the power supply subsystem 330 to increase the voltage across the one or more heating elements 120 to a first voltage, for example about 15 VDC or a first voltage range, for example about 5 VDC to about 15 VDC.

At 514, the control system 350 causes the power supply subsystem 330 to hold the temperature of the one or more heating elements 120 at the operating temperature over a third interval 430. Holding the one or more heating elements 120 at the operating temperature causes the solder 208 positioned or otherwise disposed between the one or more FCB pads 110 and corresponding ones of the one or more PCB lands 202 to reflow, thereby physically and conductively coupling the FCB 100 to the PCB 200. The control system 350 causes the power supply subsystem 330 to provide a controlled output that maintains the one or more heating elements 120 at the operating temperature for a relatively longer duration third interval 430. For example, the control system 350 causes the power supply subsystem 330 to provide a controlled output that maintains the heating element at a temperature between 290° C. and 350° C. over a third interval 430 of about 4 seconds or less.

At 516, the control system 350 causes the power supply subsystem 330 to reduce power supplied to the one or more heating elements 120 at the start of a fourth interval 440. For example, the control system 350 causes the power supply subsystem 330 to remove power from the one or more heating elements 120 at the start of the fourth interval 450. In some embodiments, the control system 350 causes the power supply subsystem 330 to maintain the voltage across the one or more heating elements 120 at a second voltage that is less than the first voltage for all or a portion of the duration of the fourth interval 450. For example, the control system 350 can cause the power supply subsystem 330 to reduce the output voltage to a second voltage that is less than 1 volt. Reducing or removing the output voltage from the one or more heating elements 120 allows the reflowed solder between the pads 110 on FCB 100 and the lands 202 on PCB 200 to cool and solidify.

At 518, the control system 350 causes the pressure application subsystem to release the pressure applied to the FCB 100 and the PCB 200 to permit the removal of the physically and conductively coupled FCB 100 and PCB 200. The method 500 concludes at 520.

1. A flexible circuit board (FCB) comprising:
a flexible dielectric layer having a first surface having a first area, a thickness, and a second surface transversely opposed across the thickness of the dielectric layer to the first surface;
one or more pads disposed on the first surface of the flexible dielectric layer; and
a heating element that includes one or more electrical traces disposed on the second surface of the dielectric layer proximate the area occupied by the one or more pads disposed on the first surface of the flexible dielectric layer
wherein the heating element includes at least two exposed terminals to receive a voltage when coupled to a removable power supply; and
wherein the heating element produces a thermal energy output of from about 0.5 W/mm² to about 2.0 W/mm² in the portion of the dielectric layer proximate the one or more pads when coupled to the removable power supply.

2. The FCB of claim 1 wherein the one or more electrical traces form a serpentine pattern on the second surface of the dielectric layer.

3. A method to conductively couple one or more pads disposed on a first surface of a flexible circuit board (FCB) to respective ones of one or more lands disposed on a surface of a printed circuit board (PCB), the method comprising:
causing, by control circuitry, an electrical connection between a variable output power supply and a heating element disposed on a second surface of the FCB transversely opposed across a thickness of the FCB to the first surface of the FCB;
wherein each of the one or more pads on the first surface of the FCB are disposed proximate solder deposited on corresponding ones of the one or more lands on the surface of the PCB; and
wherein the heating element includes one or more electrical traces disposed on the second surface of the FCB proximate the area occupied by the one or more pads disposed on the first surface of the FCB;
retrieving, by the control circuitry from memory circuitry, data representative of one or more electrical parameter profiles; and
causing a reflow of the solder between each of the one or more pads disposed on the surface of the FCB and corresponding ones of the one or more lands disposed on a surface of the PCB by:
controlling, by the control circuitry, the power supply output to the heating element such that the power supply output corresponds to the retrieved one or more electrical parameter profiles;
wherein the one or more electrical parameter profiles cause the heating element disposed on the second surface of the FCB to produce heat sufficient to cause reflow of the solder between the one or more FCB pads and corresponding ones of the PCB lands; and
causing, by the control circuitry, an external pressure application subsystem to apply pressure to the FCB and the PCB in at least the portion of the FCB occupied by the heating element.

4. The method of claim 3 further comprising:
determining by the control circuitry during a first interval, a resistance of the heating element.

5. The method of claim 4, wherein the one or more electrical parameter profiles include at least one of: a power supply output voltage profile or a power supply current output profile.

6. The method of claim 5 further comprising:
determining, by the control circuitry, one or more adjusted electrical parameter profiles using the retrieved one or more electrical parameter profiles and based on the determined resistance of the heating element.

7. The method of claim 3 wherein causing the reflow of the solder between each of the one or more pads disposed on the surface of the FCB and corresponding ones of the one or more lands disposed on a surface of the PCB comprises further comprises:
causing the reflow of solder deposited at a density of from about 0.075 mm³ solder to about 0.090 mm³ of solder per mm² of land area on each of the one or more lands disposed on the surface of the PCB to conductively couple the one or more pads on first surface of the FCB to the corresponding one or more lands on the surface of the PCB.

8. The method of claim 7 wherein controlling the power supply output to the heating element such that the output corresponds to the retrieved one or more electrical parameter profiles further comprises:
controlling, by the control circuitry, one or more output parameters of the power supply to cause the heating element to produce heat at a rate of from about 0.5 Watts/mm² of total area of the one or more FCB pads to about 2.0 Watts/mm² of total area of the one or more FCB pads.

9. The method of claim 4 wherein causing the reflow of the solder between each of the one or more pads disposed on the surface of the FCB and corresponding ones of the one or more lands disposed on a surface of the PCB comprises:
causing, by the control circuitry, an increase in power supply output voltage to a first voltage over a second interval to cause an increase in temperature of the heating element to a first temperature;
causing, by the control circuitry, the power supply output voltage to hold at the first voltage to cause the temperature of the heating element to remain in a first temperature range for a third interval sufficient to cause a reflow of the solder deposited between each of the one or more FCB pads and corresponding ones of the one or more PCB lands; and
causing, by the control circuitry, a decrease in power supply output voltage at the start of a fourth interval.

10. The method of claim 9 wherein causing the increase in temperature of the heating element to the first temperature over the second interval further comprises:
adjusting, by the control circuitry, the power supply output voltage to cause the increase in temperature of the heating element to a temperature of from about 290° C. to about 350° C. over the second interval.

11. The method of claim 10 wherein adjusting the power supply output voltage to cause the increase in temperature of the heating element to a temperature of from about 290° C. to about 350 C. over the second interval further comprises:
adjusting, by the control circuitry, the power supply output voltage to cause the increase in temperature of the heating element to a temperature of from about 290 C. to about 350 C. over the second interval, wherein the second interval has a duration of from about 1 second to about 10 seconds.

12. The method of claim 10 wherein causing the power supply output voltage to hold at the first voltage to cause the temperature of the heating element to remain in the first temperature range for a third interval further comprises:
maintaining, by the control circuitry, the power supply output voltage at a level sufficient to cause the temperature of the heating element to remain in a temperature range of from about 270 C. to about 350 C. over the third interval.

13. The method of claim 12 wherein maintaining the power supply output voltage at the level sufficient to cause the temperature of the heating element to remain in the temperature range of from about 270 C. to about 350 C. over the third interval further comprises:
adjusting, by the control circuitry, the power supply output voltage to cause the temperature of the heating element to remain in the temperature range of from about 270 C. to about 350 C. over the third interval, wherein the third interval has a duration of from about 1 second to about 10 seconds.

14. The method of claim 13 wherein causing the decrease in power supply output voltage at the start of the fourth interval further comprises:
causing, by the control circuitry, the power supply output voltage to decrease to a second voltage less than the first voltage at the start of the fourth interval, the reduction in voltage to provide cooling interval having a duration of from about 1 seconds to about 10 seconds.

15. The method of claim 14, wherein causing the power supply output voltage to decrease to the second voltage less than the first voltage at the start of the fourth interval further comprises:
causing, by the control circuitry, the power supply output voltage to decrease to zero volts for the duration of the fourth interval.

16. The method of claim 3 wherein causing the reflow of the solder between each of the one or more pads disposed on the surface of the FCB and corresponding ones of the one or more lands disposed on a surface of the PCB further comprises:
causing, by the control circuitry, the reflow of a solder deposited at a density of from about 0.030 mm³ solder to about 0.050 mm³ solder per mm² of land area on each respective one of the one or more lands disposed on the surface of the PCB.

17-58. (canceled)
